(19) United States
(12) Patent Application Publication
(10) Pub. No.: US 2026/0115998 A1
(43) Pub. Date: Apr. 30, 2026

(54) MULTIPHASIC MICROFLUIDIC METHOD FOR ADAPTIVE MULTI-MATERIAL 3D PRINTING

(71) Applicant: Board of Regents, The University of Texas System, Austin, TX (US)

(72) Inventors: GUILLERMO RAMIREZ, San Antonio, TX (US); GABRIEL GARIBALDI, San Antonio, TX (US); GONGCHEN SUN, San Antonio, TX (US)

(21) Appl. No.: 19/368,316

(22) Filed: Oct. 24, 2025

Related U.S. Application Data
(60) Provisional application No. 63/711,205, filed on Oct. 24, 2024.

(51) Int. Cl. B29C 64/124; B29C 64/286; B29C 64/336; B29K 33/00; B33Y 10/00; B33Y 70/00; B81C 1/00

(52) U.S. Cl. CPC B29C 64/124; B29C 64/286; B29C 64/336; B81C 1/00373; B29K 2033/08; B33Y 10/00; B33Y 70/00

(57) ABSTRACT

Stereolithography (SLA)-based 3D printing enables high-resolution microfabrication but faces challenges in multi-material integration and adaptive Z-layer control due to reliance on vats and mechanical stages. We introduce “In-situ 3D Polymerization” (IS-3DP), a novel method leveraging multiphasic laminar flow in a microfluidic channel to fabricate three-dimensional microstructures. By combining in-situ polymerization with an aqueous two-phase system (ATPS), IS-3DP dynamically controls layer thickness through flow rate adjustments, achieving resolutions below 200 μm. This approach eliminates vats, reducing material consumption by an order of magnitude, and enables rapid multi-material switching without complex printer modifications. Compatible with various light sources and photopolymers, IS-3DP offers versatile applications in bioprinting and microdevice manufacturing, with demonstrated layer-by-layer printing of 3D structures in a microfluidic environment.

This application claims priority to U.S. Provisional Application 63/711,205 filed Oct. 24, 2024 which is incorporated herein by reference in its entirety.

### STATEMENT REGARDING FEDERALLY FUNDED RESEARCH

None.

### FIELD

Certain aspects of the invention are directed to additive manufacturing systems and methods utilizing multiphasic laminar flow within microfluidic channels for dynamic layer thickness control and in-situ photopolymerization. The invention provides solutions for high-resolution 3D printing without mechanical stages or resin vats, enabling efficient multi-material integration for microfabrication and bioprinting applications.

### BACKGROUND

Recent advances in 3D printing have transformed microfabrication, enabling the creation of complex microfluidic devices with intricate 3D geometries at lower costs and faster prototyping speeds compared to traditional soft lithography [1-4]. These advancements have expanded applications, such as high-density microfluidic valves, pumps, mixers, and integrated capillaric circuits for programmed reactions [5-9]. Among 3D printing techniques, stereolithography (SLA) is preferred for microscale fabrication due to its high XY-plane resolution, achieving features as small as 50 nm with advanced methods like two-photon polymerization and microfluidic channels as fine as 18 μm×20 μm [10-19].

In conventional SLA, 3D objects are built by stacking 2D slices formed through light-induced polymerization of photopolymer resins in a vat [20]. A motorized stage moves a build-plate to define layer thickness in the Z-direction, typically fixed for each print [21, 22]. This approach presents two key challenges. First, fixed layer thickness can lead to prolonged printing times for large Z-dimension objects and unintended polymerization due to light bleed, reducing precision. Adaptive layer thickness control is possible but requires complex modifications to slicing software and mechanical stages [23]. Second, multi-material printing necessitates multiple vats for different resins, increasing printer complexity and requiring extensive washing steps during material switches [24, 25].

Current SLA techniques face significant limitations in achieving adaptive layer thickness control and efficient multi-material printing. Fixed layer thicknesses, dictated by mechanical stages, result in prolonged printing times and unintended polymerization due to light bleed, compromising precision for large Z-dimension objects [23]. Multi-material printing requires multiple vats, increasing printer complexity and necessitating time-consuming washing steps during resin switches [24, 25]. Additionally, vat-based systems consume excessive material and are prone to delamination defects, limiting their suitability for applications like bioprinting. Advances are needed to enable dynamic Z-layer control without complex software or hardware modifications, streamline multi-material integration with minimal material waste, and eliminate mechanical components to enhance precision and efficiency.

### SUMMARY

The present invention provides solutions to the problems described above through In-situ 3D Polymerization (IS-3DP), by leveraging multiphasic laminar flow in a microfluidic channel to dynamically control layer thickness and facilitate rapid material switching.

In certain embodiments, an additive manufacturing method, termed In-situ 3D Polymerization (IS-3DP), addresses limitations of traditional stereolithography (SLA) by utilizing multiphasic laminar flow in a microfluidic channel. This approach integrates a light engine with precise flow control to fabricate three-dimensional objects without mechanical stages or resin vats.

In certain embodiments, the method establishes a laminar flow comprising two immiscible liquid phases—a photopolymerizable resin and a blocking solution a within a microfluidic channel. Adjusting the flow rate ratio between these phases enables dynamic control of printing layer thickness, facilitating customized layer-by-layer construction.

In certain embodiments, a light engine selectively exposes the resin phase to patterned light, polymerizing specific regions to form solidified layers. This process, repeated with coordinated flow adjustments and light exposure, builds complex 3D structures with reduced printing time and enhanced precision compared to conventional SLA.

In certain embodiments, the microfluidic system eliminates the need for vats, significantly reducing material consumption. Rapid switching of resins within the system enables multi-material printing, allowing seamless integration of different photopolymers in a single print.

In certain embodiments, the IS-3DP system includes a microfluidic device, pumps for controlling flow rates, a light engine for polymerization, and a controller to synchronize operations. This configuration supports efficient and precise fabrication of 3D structures.

In certain embodiments, the composition for IS-3DP comprises a resin phase, such as poly(ethylene glycol) diacrylate with a photoinitiator, and a dextran-based blocking solution. These phases form a stable interface in the microfluidic channel, enabling precise layer formation for applications in bioprinting, microdevice manufacturing, and beyond.

Other embodiments of the invention are discussed throughout this application. Any embodiment discussed with respect to one aspect of the invention applies to other aspects of the invention as well and vice versa. Each embodiment described herein is understood to be embodiments of the invention that are applicable to all aspects of the invention. It is contemplated that any embodiment discussed herein can be implemented with respect to any method or composition of the invention, and vice versa. Furthermore, compositions and kits of the invention can be used to achieve methods of the invention.

The use of the word “a” or “an” when used in conjunction with the term “comprising” in the claims and/or the specification may mean “one,” but it is also consistent with the meaning of “one or more,” “at least one,” and “one or more than one.”

Throughout this application, the term “about” is used to indicate that a value includes the standard deviation of error for the device or method being employed to determine the value.

The use of the term “or” in the claims is used to mean “and/or” unless explicitly indicated to refer to alternatives only or the alternatives are mutually exclusive, although the disclosure supports a definition that refers to only alternatives and “and/or.”

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

As used herein, the terms “comprises,” “comprising,” “includes,” “including,” “has,” “having,” “contains”, “containing,” “characterized by” or any other variation thereof, are intended to encompass a non-exclusive inclusion, subject to any limitation explicitly indicated otherwise, of the recited components. For example, a chemical composition and/or method that “comprises” a list of elements (e.g., components or features or steps) is not necessarily limited to only those elements (or components or features or steps), but may include other elements (or components or features or steps) not expressly listed or inherent to the chemical composition and/or method.

As used herein, the transitional phrases “consists of” and “consisting of” exclude any element, step, or component not specified. For example, “consists of” or “consisting of” used in a claim would limit the claim to the components, materials or steps specifically recited in the claim except for impurities ordinarily associated therewith (i.e., impurities within a given component). When the phrase “consists of” or “consisting of” appears in a clause of the body of a claim, rather than immediately following the preamble, the phrase “consists of” or “consisting of” limits only the elements (or components or steps) set forth in that clause; other elements (or components) are not excluded from the claim as a whole.

As used herein, the transitional phrases “consists essentially of” and “consisting essentially of” are used to define a chemical composition and/or method that includes materials, steps, features, components, or elements, in addition to those literally disclosed, provided that these additional materials, steps, features, components, or elements do not materially affect the basic and novel characteristic(s) of the claimed invention. The term “consisting essentially of” occupies a middle ground between “comprising” and “consisting of”.

Other objects, features and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

Definitions—For the purposes of this patent application, the following terms shall have the meanings set forth below unless otherwise indicated by the context.

The term “multiphasic laminar flow” refers to the streamlined flow of two or more immiscible liquid phases within a microfluidic channel, wherein the phases maintain distinct boundaries due to laminar flow characteristics, enabling precise control of layer formation.

The term “photopolymerizable resin” refers to a liquid material capable of solidifying upon exposure to light, typically comprising a polymer precursor, such as poly(ethylene glycol) diacrylate (PEG-DA), and a photoinitiator that initiates polymerization.

The term “blocking solution” refers to a liquid phase, such as a dextran solution, that is immiscible with the photopolymerizable resin and does not polymerize under light exposure, used to control the thickness of the printing layer in the microfluidic channel.

The term “microfluidic channel” refers to a confined conduit, typically with dimensions on the order of micrometers to millimeters, designed to support the flow of small volumes of liquids for precise manipulation in the IS-3DP process.

The term “light engine” refers to a system that delivers patterned light, such as a UV projector or masked light source, to selectively polymerize the photopolymerizable resin in the IS-3DP method.

The term “printing layer” refers to a thin layer of photopolymerizable resin formed within the microfluidic channel, the thickness of which is controlled by the flow rate ratio of the multiphasic laminar flow, used to create a solidified layer of the three-dimensional object.

The term “In-situ 3D Polymerization (IS-3DP)” refers to the additive manufacturing method described herein, which uses multiphasic laminar flow in a microfluidic channel to dynamically control layer thickness and enable multi-material 3D printing without mechanical stages or vats.

The term “flow rate ratio” refers to the ratio of the flow rates between the photopolymerizable resin phase and the blocking solution phase, adjusted to control the thickness of the printing layer in the IS-3DP process.

### DESCRIPTION OF THE DRAWINGS

The following drawings form part of the present specification and are included to further demonstrate certain aspects of the present invention. The invention may be better understood by reference to one or more of these drawings in combination with the detailed description of the specification embodiments presented herein.

FIG. 1A-1D. Overview of the in-situ 3D printing (IS-3DP) platform and printing workflow. (A) A custom frame was designed to house the IS-3DP printer, which integrates two main subsystems: the printing stage and the motorized XYZ platform. (B) The printing stage includes a high-resolution UV light engine, two commercial syringe pumps for flow control, and a camera system positioned beneath the projection zone. The motorized XYZ platform enables movement along all three axes, while the bottom-mounted camera facilitates projector-camera alignment and in-situ monitoring during printing. (C) A single-channel microfluidic device was fabricated using conventional SLA 3D printing. The chip contains two inlets, one for the printing (polymerizable) solution and another for the blocking (non-polymerizable) phase, and a single outlet for waste removal. (D) The IS-3DP fabrication process proceeds in two main phases: flow and polymerization. During the flow phase, the fluid interface is dynamically adjusted to define the layer height. In the polymerization phase, a selected 2D pattern is UV-exposed to solidify the desired layer. Complex 3D structures are produced by alternating these two steps: controlling layer height through flow and defining geometry through patterned exposure.

FIG. 2. The IS-3DP printing procedure. The procedure includes two key steps: Step 1, layer formation, followed by Step 2, polymerization. Layer formation uses a specific combination of flow rates of the two phases. By initiating masked light exposure in the polymerization step, the multi-phase flow-established printing layer can be polymerized through. These two steps can be repeated to form three-dimensional structures.

FIG. 3A-3B. (A) Phase diagram showing operation zones with varying flow rates. Flow rate combinations used for testing are marked with a black checkmark. (B) Flow profile analysis in-silico (COMSOL) against experimental. The color coding represents the interface phase change in the simulation with Dex representing phase 1, denoted in red, and PEG-DA representing phase 0, denoted in blue. The experimental data shows the average normalized interface height and error bar from four technical repeats.

FIG. 4A-4B. (A) Experimental data showing three different printed layer thicknesses under different inlet flow rate ratios. Channel walls are boxed in red, while the polymerized structure is boxed in green. Two different masks with same rectangular shape but different lengths were used: Mask 1 for Thickness 1 (bottom panel) and Mask 2 for Thickness 2 and 3 (top and middle panel). (B) Interface height in the ATPS co-flow profile were included to compare with the thickness of the polymerized structure.

FIG. 5A-5B. (A) A COMSOL simulation comparing interface height in two scenarios, the distance between the interface and the channel wall and the distance between interface and the edge of an internal structure. (B) 3D image of a three-layer printed structure in the microchannel using the IS-3DP strategy. The 3D perspective image was generated through z-stacking of 10 image slices. The thicknesses of the first, second, and third printed layer were measured to be 194 μm, 299 μm, and 314 μm, respectively.

FIG. 6A-6B. (A) Isometric view of the CAD design for the microfluidic chip. The chip size is indicated by the red scale, showing a width of 1 mm. (B) Side view of the chip design depicting two inlets and one outlet, as indicated by the red arrows. The main channel dimensions are 40 mm in length and 2 mm in height.

FIG. 7. A series of different time stamps of the ATPS interface forming and stabilizing within 5 seconds at a 7.78% flow rate ratio.

FIG. 8. Linear Regression fit of the interface height against varying flow rate ratios depicts a consistent, monotonic trend.

FIG. 9A-9C. Dynamic layer height control and the influence of phase viscosity ratio on minimum printable thickness. (A) To evaluate the lower limits of layer formation in the IS-3DP system, the printing phase (PEGDA 575 Da) and the blocking phase (Dextran 150 kDa) were co-flowed within a single channel. PEGDA flow rates ranged from 0.01 to 0.05 mL/min, while Dextran flow rates ranged from 0.1 to 0.5 mL/min. Four viscosity ratios between the two phases were tested. The resulting layer heights were quantified through image analysis when the chip was imaged on its side, with three trials performed per condition. (B) Minimum layer heights were plotted against the viscosity ratio and expressed as relative percentages. Increasing the Dextran-to-PEGDA viscosity ratio produced thinner layers, reducing the minimum attainable layer height by up to ˜33%. (C) The dynamic printing range, defined as the span between the minimum and maximum achievable layer heights, was found to be dependent on the viscosity ratio. Lower viscosity ratios exhibited wider tunable ranges, whereas higher ratios constrained the layer-height adjustability.

FIG. 10A-10C. Camera-projector alignment and homography calibration for precise pattern projection (A) Front view of the IS-3DP printing system showing the spatial arrangement of the light engine (projector), build stage, and bottom-mounted camera. The camera is positioned beneath the build stage to capture projected patterns from below. A representative bottom-view inset illustrates how the camera observes the build zone during projection. (B) A custom graphical user interface (GUI) was developed to visualize and align projected shapes within the camera's field of view prior to exposure. The GUI supports loading predesigned image slices or generating simple geometric shapes (e.g., squares, triangles, circles). Manual shape alignment is achieved through a homography-based mapping system that ensures projector-camera mapping. The user is able to visualize and move the projection before exposure. An example alignment of a “worm”-shaped projection with the channel geometry is shown. (C) Flow diagram of the homography calibration process. The projector sequentially displays 40 dots at predefined coordinates. For each dot, the camera captures multiple frames, the centroid is detected and averaged, and both the projector coordinates (xₚ, yₚ) and camera coordinates (x_{c}, y_{c}) are recorded. Using these point correspondences, the 3×3 homography matrix H is computed according to [xₚ, yₚ, 1]^{T}˜H[x_{c}, y_{c}, 1]^{T}, enabling projection alignment during printing.

FIG. 11A-11B. Demonstration of complex 3D structures fabricated using the IS-3DP method. (A) A five-layer triangular pyramid was constructed using the highest tested viscosity ratio between the Dextran and PEGDA phases (μDex/μPEGDA=0.49). Dextran was maintained at a constant flow rate of 0.5 mL/min, while PEGDA flow was varied from 0.01 mL/min to 0.05 mL/min to control layer height. The 3D render was generated from stacked side-view images. (B) A bridge structure with an internal void was fabricated. The design consisted of four layers: two circular pillar layers followed by two bridge layers spanning the gap. Perspective and side-view renders are shown alongside highlighted key features (pillar, bridge, void, and wall regions).

### DESCRIPTION

The following discussion is directed to various embodiments of the invention. The term “invention” is not intended to refer to any particular embodiment or otherwise limit the scope of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be an example of that embodiment, and not intended to imply that the scope of the disclosure, including the claims, is limited to that embodiment.

### I. ADDITIVE MANUFACTURING OF A THREE-DIMENSIONAL (3D) OBJECT

In certain embodiments, the present invention, In-situ 3D Polymerization (IS-3DP), provides a method for additive manufacturing of three-dimensional objects using multiphasic laminar flow in a microfluidic channel. Unlike traditional stereolithography (SLA), which relies on mechanical stages and resin vats, IS-3DP employs a photopolymerizable resin and a blocking solution to dynamically form and solidify printing layers without mechanical components. This approach reduces material consumption, enables rapid multi-material integration, and enhances precision, making it suitable for applications such as bioprinting and microdevice fabrication.

Conventional SLA techniques face challenges in achieving adaptive layer thickness control and efficient multi-material printing due to their dependence on fixed mechanical stages and multiple vats. Fixed layer thicknesses lead to prolonged printing times and unintended polymerization from light bleed, while multi-vat systems increase complexity and require extensive washing steps for material switches. The IS-3DP method addresses these issues by using multiphasic laminar flow to control layer thickness dynamically and eliminate vats, thereby reducing material waste and simplifying multi-material printing. This innovation leverages microfluidic principles to offer a more efficient and versatile alternative to traditional SLA.

In certain embodiments, IS-3DP operates by establishing a multiphasic laminar flow of a photopolymerizable resin phase and an immiscible blocking solution phase within a microfluidic channel. The flow rate ratio between these phases is adjusted to control the printing layer thickness, followed by selective exposure to patterned light from a light engine to polymerize the resin, forming a solidified layer. This process is repeated to build 3D structures layer by layer. The system comprises a microfluidic device with a channel for laminar flow, pumps to adjust flow rates, a light engine (e.g., UV projector or masked light source) for polymerization, and a controller to synchronize operations, enabling precise and efficient fabrication without mechanical stages or vats.

### A. Microfluidic Flow Control

In certain embodiments, the IS-3DP method utilizes multiphasic laminar flow within a microfluidic channel to precisely control the thickness of the printing layer. Two immiscible liquid phases—a photopolymerizable resin and a blocking solution—are introduced through separate inlets into the microfluidic channel. The laminar flow characteristics ensure that these phases maintain a stable, planar interface, allowing the resin phase to form a thin, controllable printing layer adjacent to the channel wall, while the blocking solution acts as a spacer to define its thickness.

The flow rate ratio between the photopolymerizable resin and the blocking solution can be adjusted to dynamically control the printing layer thickness. By varying the flow rates using pumps, such as syringe or pneumatic pumps, the position of the phase interface can be tuned, enabling layer thicknesses to be customized for each printing cycle. Experimental results demonstrate that the interface stabilizes rapidly, typically within 5 seconds, ensuring consistent layer formation across a range of flow conditions.

The flow control system may facilitate rapid switching of the resin phase to enable multi-material printing. By sequentially introducing different photopolymerizable resins through the same inlet, the system allows for seamless transitions between materials without requiring additional washing steps or multiple vats. This capability enhances the efficiency and versatility of the IS-3DP process, supporting the fabrication of complex, multi-material 3D structures.

The stability and precision of the multiphasic laminar flow can be validated through numerical simulations and experimental measurements. Computational fluid dynamics models predict the interface position with high accuracy, aligning closely with observed layer thicknesses. These results confirm that the flow control system reliably produces printing layers suitable for high-resolution microfabrication applications, such as bioprinting and microdevice manufacturing.

### B. Light Exposure and Polymerization

In certain embodiments, the IS-3DP method employs a light engine to selectively expose the photopolymerizable resin phase within the microfluidic channel to patterned light, initiating polymerization to form solidified layers. The light engine, which may include a UV projector or a masked light source, delivers light at specific wavelengths to trigger the photoinitiator in the resin, creating precise two-dimensional patterns that define each layer of the three-dimensional object.

The light exposure process can be coordinated with the multiphasic laminar flow to ensure accurate polymerization of the printing layer. The blocking solution phase, positioned between the resin and the light source, prevents unintended polymerization by absorbing or deflecting excess light. Exposure parameters, such as duration and intensity, are adjusted based on the resin's properties and desired layer thickness to achieve optimal solidification without affecting adjacent regions.

The light engine may incorporate a customizable mask or digital projection system to control the spatial pattern of light exposure. Masks, either physical or digitally generated, enable the formation of complex geometries, such as rectangular or curved structures, within the microfluidic channel. The light engine's position is adjustable, often via a motorized stage, to maintain focus on the printing layer, ensuring high-resolution fabrication.

The polymerization process may be validated through experimental results demonstrating consistent layer formation. Tests with varying exposure times and mask designs confirm that the solidified layers align with the intended patterns, supporting the method's capability to produce intricate three-dimensional structures with high precision for applications in microfabrication and bioprinting.

### C. Interface Characterization and Imaging

In certain embodiments, the IS-3DP method employs fluorescence microscopy to characterize the interface between the photopolymerizable resin and the blocking solution in the microfluidic channel. A fluorescent dye, such as sodium fluorescein, is added to one of the phases to enhance visibility of the phase boundary under a microscope. This technique allows precise measurement of the interface position and stability, critical for ensuring consistent printing layer thickness during the additive manufacturing process.

In certain other embodiments, side-view imaging is utilized to monitor the multiphasic laminar flow and confirm the formation of a stable, planar interface. The microfluidic device is designed with protruding side channels or transparent walls to enable direct observation of the phase boundary. Imaging data reveal that the interface stabilizes rapidly, typically within 5 seconds, under various flow rate conditions, supporting reliable layer-by-layer fabrication.

The characterization process may include quantitative analysis of the interface height to validate the control of printing layer thickness. By correlating imaging results with flow rate ratios, the system demonstrates precise tuning of layer dimensions, achieving thicknesses suitable for high-resolution 3D printing. Experimental measurements align closely with numerical simulations, confirming the accuracy of interface predictions for microfabrication applications.

The imaging techniques can be integrated with the IS-3DP system to provide real-time feedback during printing. A camera system, synchronized with the controller, captures interface behavior to ensure alignment with the light engine's exposure patterns. This integration enhances the method's reliability, enabling the production of complex three-dimensional structures for applications such as bioprinting and microdevice manufacturing.

### D. Multi-Material Integration

In certain embodiments, the IS-3DP method enables multi-material 3D printing by facilitating rapid switching of different photopolymerizable resins within the microfluidic channel. The system's design allows sequential introduction of distinct resin phases through a single inlet, leveraging the laminar flow characteristics to maintain a stable interface with the blocking solution. This approach eliminates the need for multiple vats or extensive washing steps, streamlining the integration of various materials in a single print.

The process of resin switching can be controlled by precise pump systems that adjust the flow of each resin phase. By coordinating the timing and sequence of resin delivery, the IS-3DP method ensures that each printing layer can incorporate a different photopolymer, enabling the fabrication of complex structures with varying material properties, such as stiffness or bioactivity. This capability is advantageous for applications requiring heterogeneous material compositions, such as tissue engineering scaffolds.

The multi-material integration process may be supported by the microfluidic device's ability to maintain interface stability during resin transitions. Experimental results demonstrate that the system can switch between resins without disrupting the laminar flow, ensuring consistent layer formation. The rapid stabilization of the phase interface, typically within seconds, supports seamless transitions between materials, enhancing printing efficiency.

The multi-material capability can be validated through the fabrication of layered structures with distinct resin compositions. Tests confirm that the IS-3DP method can produce three-dimensional objects with precise material boundaries, suitable for applications in bioprinting and microdevice manufacturing. The system's versatility allows for the integration of multiple photopolymers, expanding the potential for creating advanced functional devices.

### II. MATERIALS AND COMPOSITIONS

In certain embodiments, the IS-3DP method utilizes a photopolymerizable resin as the printing layer material, formulated to solidify upon exposure to light. The resin typically comprises a polymer precursor, such as poly(ethylene glycol) diacrylate (PEG-DA), combined with a photoinitiator that triggers polymerization under specific wavelengths, such as ultraviolet light. The resin is selected for its ability to form a stable, immiscible interface with the blocking solution, ensuring precise layer formation within the microfluidic channel.

The blocking solution can be an aqueous phase, such as a dextran-based solution, designed to be immiscible with the photopolymerizable resin and inert to light exposure. The blocking solution acts as a spacer to control the thickness of the printing layer by maintaining a stable laminar flow interface. Its viscosity and density are tailored to complement the resin's properties, enabling consistent flow dynamics and preventing intermixing during printing.

The compositions of the resin and blocking solution can be optimized for compatibility with multi-material printing. Multiple photopolymerizable resins with varying properties, such as different mechanical strengths or biofunctional characteristics, can be sequentially introduced to create heterogeneous structures. The immiscibility between the resin and blocking solution supports rapid material switching without requiring washing steps, enhancing efficiency in applications like bioprinting.

### B. Fabrication of the Microfluidic Device

In certain embodiments, the microfluidic device for the IS-3DP method is fabricated using additive manufacturing techniques, such as stereolithography (SLA), to create a channel structure that supports multiphasic laminar flow. The device is constructed from a photopolymer resin, ensuring compatibility with the photopolymerizable resin and blocking solution used in the printing process. The fabrication process involves printing the channel geometry with high precision to maintain consistent flow dynamics and interface stability.

The microfluidic chip can feature a rectangular channel with multiple inlets and outlets to facilitate the introduction and removal of the photopolymerizable resin and blocking solution. The channel dimensions, typically on the order of micrometers to millimeters, are designed to promote laminar flow and minimize turbulence, ensuring a stable phase interface. Additional structural features, such as protruding side channels, may be incorporated to enable side-view imaging for interface characterization.

The fabrication process may include post-processing steps to enhance the device's functionality. After printing, the chip is cleaned to remove residual resin, cured to ensure structural integrity, and bonded to a transparent substrate, such as glass or a clear polymer, to allow light penetration for polymerization. These steps ensure the microfluidic device is suitable for high-resolution printing and imaging applications.

In certain embodiments, the microfluidic device's design is validated through experimental testing, confirming its ability to maintain stable multiphasic flow and support precise layer formation. The fabricated channels demonstrate compatibility with various flow rates and resin types, enabling the production of complex three-dimensional structures for applications in microfabrication and bioprinting.

### B. Design of the Microfluidic Chip

In certain embodiments, the microfluidic chip for the IS-3DP method is designed with a primary channel configured to support multiphasic laminar flow of a photopolymerizable resin and a blocking solution. The channel, typically rectangular in cross-section, is engineered to minimize turbulence and ensure a stable, planar interface between the immiscible phases, facilitating precise control of the printing layer thickness. The channel's dimensions are optimized to maintain consistent flow dynamics across a range of flow rates.

The chip may incorporate multiple inlets to introduce the photopolymerizable resin and blocking solution separately, ensuring controlled delivery of each phase into the primary channel. A single outlet is included to remove excess fluids, maintaining steady flow conditions. The inlet and outlet configurations are designed to support rapid switching of different resin phases, enabling multi-material printing without disrupting the laminar flow interface.

The microfluidic chip may include structural features to facilitate interface characterization and imaging. Protruding side channels or transparent walls are integrated to enable side-view observation of the phase boundary, critical for validating interface stability and layer thickness. These features allow for fluorescence microscopy or other imaging techniques to monitor the printing process in real time.

The chip's design may be validated through experimental testing, confirming its ability to support stable laminar flow and precise layer formation. The channel geometry and structural features ensure compatibility with the light engine's exposure patterns, enabling the fabrication of high-resolution three-dimensional structures suitable for applications in bioprinting and microdevice manufacturing.

### III. METHOD OF OPERATION

In certain embodiments, the IS-3DP method begins by establishing a multiphasic laminar flow within a microfluidic channel, introducing a photopolymerizable resin phase and an immiscible blocking solution phase through separate inlets. The laminar flow ensures a stable, planar interface between the phases, with the resin forming a thin printing layer adjacent to the channel wall and the blocking solution acting as a spacer to define its thickness. This step eliminates the need for mechanical stages or vats used in traditional stereolithography.

The flow rate ratio between the photopolymerizable resin and the blocking solution may be adjusted using pumps to control the thickness of the printing layer. By varying the relative flow rates, the position of the phase interface is tuned, allowing for dynamic customization of layer thickness for each printing cycle. The interface stabilizes rapidly, enabling consistent layer formation suitable for high-resolution 3D printing.

The printing layer may be selectively exposed to patterned light from a light engine, such as a UV projector or masked light source, to initiate polymerization of the resin. The light engine projects a two-dimensional pattern, solidifying the resin into a defined layer while the blocking solution prevents unintended polymerization. The exposure parameters, including duration and intensity, are synchronized with the flow conditions to ensure precise layer formation.

The process may be repeated iteratively to build three-dimensional structures layer by layer. After each layer is solidified, the flow is adjusted to form a new printing layer, and the light exposure is repeated with the appropriate pattern. This iterative process, controlled by a synchronized system, supports the fabrication of complex geometries and multi-material structures, enabling applications in bioprinting and microdevice manufacturing.

### A. Control Systems and Automation

In certain embodiments, the IS-3DP method employs a control system to synchronize the operation of the microfluidic device, pumps, and light engine, enabling precise layer-by-layer fabrication of three-dimensional objects. The controller, which may include a microcontroller or computer-based system, coordinates the timing of flow rate adjustments and light exposure sequences to ensure accurate printing layer formation and polymerization within the microfluidic channel.

The control system may automate the adjustment of flow rate ratios between the photopolymerizable resin and blocking solution phases. By interfacing with programmable pumps, such as syringe or pneumatic pumps, the controller dynamically tunes the phase interface position to achieve desired printing layer thicknesses. This automation supports rapid transitions between different resins, facilitating multi-material printing without manual intervention.

The control system can integrate with an optional camera system to provide real-time feedback during the printing process. The camera, used for interface characterization, captures images of the phase boundary, which the controller processes to verify alignment with the light engine's exposure patterns. Techniques such as homography calibration are employed to ensure precise positioning of the patterned light relative to the printing layer.

The automation process can be validated through experimental results demonstrating consistent layer formation and interface stability. The control system's ability to synchronize flow and exposure sequences enables the fabrication of complex structures with high precision, supporting applications in bioprinting and microdevice manufacturing. This automated approach enhances the efficiency and reliability of the IS-3DP method compared to traditional stereolithography systems.

### B. Numerical Simulations

In certain embodiments, numerical simulations are employed to model the multiphasic laminar flow dynamics within the microfluidic channel of the IS-3DP method. Computational fluid dynamics (CFD) techniques are used to predict the position and stability of the interface between the photopolymerizable resin and the blocking solution, enabling precise control of the printing layer thickness. These simulations account for fluid properties, such as viscosity and density, and flow conditions to optimize the system's performance.

The simulations may provide quantitative predictions of the phase interface height as a function of the flow rate ratio between the resin and blocking solution. By modeling the laminar flow behavior, the simulations demonstrate how adjustments in flow rates can dynamically tune the printing layer thickness, supporting the method's ability to achieve high-resolution 3D printing without mechanical stages.

The results of numerical simulations may be validated against experimental measurements, showing close agreement in interface position and layer thickness. For example, simulated interface heights align within a small margin of experimental data, confirming the accuracy of the predictive models. This correlation ensures that the simulations serve as a reliable tool for designing and optimizing the microfluidic system.

The numerical simulations may be extended to explore multi-material printing scenarios, predicting the behavior of different resin phases during rapid switching. These models help identify optimal flow conditions to maintain interface stability during material transitions, enhancing the efficiency and versatility of the IS-3DP method for applications in bioprinting and microdevice manufacturing.

### C. Performance Metrics and Validation

In certain embodiments, the IS-3DP method demonstrates precise control over printing layer thickness, achieving a range of thicknesses suitable for high-resolution microfabrication. Experimental results validate that the system can form layers with adjustable thicknesses by tuning the flow rate ratio of the photopolymerizable resin and blocking solution, enabling the fabrication of three-dimensional structures with consistent dimensions. These metrics confirm the method's ability to produce layers finer than those in traditional SLA systems, which are limited by fixed mechanical stages.

The stability of the multiphasic laminar flow interface may be validated through measurements showing rapid stabilization, typically within 5 seconds, across various flow conditions. This quick stabilization ensures reliable layer formation, minimizing disruptions during printing. Interface stability is further corroborated by fluorescence microscopy, which demonstrates a planar phase boundary critical for precise polymerization and layer stacking in the microfluidic channel.

In certain embodiments, numerical simulations, such as those performed using computational fluid dynamics, predict interface heights with high accuracy, aligning within approximately 3% of experimental measurements. These simulations validate the relationship between flow rate ratios and layer thickness, providing a predictive tool for optimizing printing parameters. The agreement between simulated and experimental results underscores the method's reliability for consistent layer-by-layer fabrication.

The IS-3DP method's performance can be demonstrated through the successful fabrication of complex structures, such as multi-layered objects and intricate geometries, with high precision. Compared to traditional SLA, IS-3DP reduces material consumption and printing time while eliminating delamination defects associated with vat-based systems. These validated outcomes support the method's applicability in bioprinting, microdevice manufacturing, and other high-resolution 3D printing applications.

### IV. EXAMPLES

The following examples as well as the figures are included to demonstrate preferred embodiments of the invention. It should be appreciated by those of skill in the art that the techniques disclosed in the examples or figures represent techniques discovered by the inventors to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the spirit and scope of the invention.

### A. Materials and Methods

### 1. IS-Printer and IS-3DP Procedure

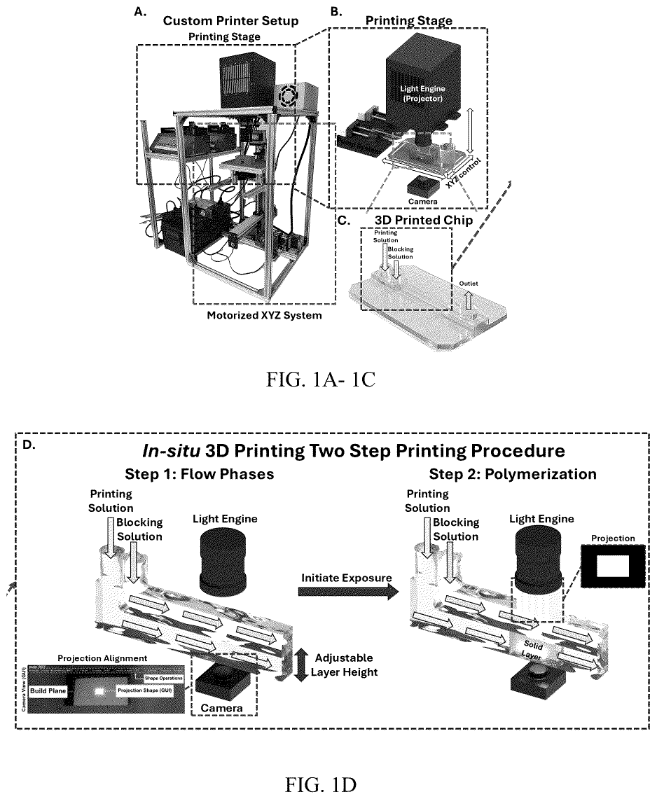

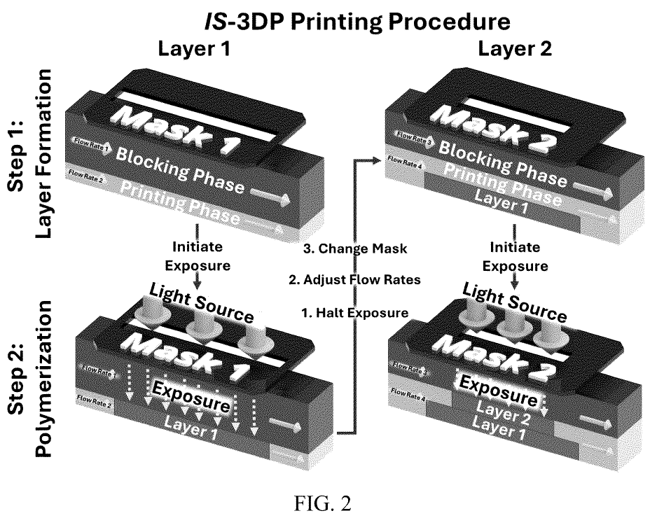

To provide a proof-of-concept validation of the IS-3DP strategy, we developed a custom 3D printer, termed the in-situ printer (IS-printer). A custom frame was built to house the IS-printer (FIGS. 1a and 1b), constructed using European standard aluminum T-shape extrusions to facilitate customization. The printer is composed of two main components: (1) Light Engine System (FIG. 1b) and FIG. 2) ATPS pumping system (FIG. 1d). A microfluidic device for vertically aligned ATPS co-flow and two syringe pumps together form the ATPS pumping system. The microfluidic chip serves as the container for the printing material (FIG. 1e); the ATPS co-flow is controlled by the syringe pumps. These components synergistically facilitate the formation of the adjustable ATPS layer thickness and the polymerization of the pre-polymer material. As shown in FIG. 1c, IS-3DP follows a simple printing procedure. The first step is the formation of the printing layer without light exposure, followed by selective polymerization via masked light exposure. The printing layer with a specific thickness is established by a certain flow rate combination of the blocking solution phase and the photopolymer solution phase after the stabilization of the interface within 5 seconds. After the polymerization of one layer, the flow rates are adjusted to establish a new phase boundary (FIG. 1c and FIG. 2). The printing procedure (FIG. 2) is repeated to print the next layer and hence build the 3D object. The co-flow ATPS is established vertically with the non-reactive blocking solution phase between the photopolymer phase and the light source. This way, the blocking solution serves dual purposes: (1) adjust the layer thickness of the printing layer; (2) protect the printed layer from being exposed to light directly causing unintended polymerization.

Light Engine System: The projection system is composed of a customized light engine attached to a FUYU FSL40 Linear Rail Guide with a NEMA 23 stepper motor that allows for movement of the focal plane and generated masks. This stepper motor is powered by a 24V power supply and controlled through a STEPPERONLINE CNC Stepper Motor Driver and an Arduino Uno. The light engine is precisely moved along the linear guide to a position where the mask/image is sharply focused, ensuring clear and accurate polymerization. The light source and mask generator can be any compatible equipment that matches the requirements of the photopolymer composition. To demonstrate the generalizability of this set up, we tested two different light sources and mask generators: (1) a low-grade DLP projector (ViewSonic PA503W); (2) a 405 nm UV light (CHANZON High Power LED Chip 10W) coupled with customized 3D printed masks.

Flow System: Two commercial syringe pumps (NE-4000 from New Era Pump Systems) were used as a base for the pumping mechanism. The syringes' stepper motors were disconnected from their original controller boards and then connected and controlled through two A4988 driver modules (attached to a CNC shield) and an Arduino Uno. The motors are powered by a 12V power supply. A custom script was developed to calibrate and operate the pumps, allowing for precise interaction with the light engine system.

### 2. Chip Fabrication

The microfluidic chip used for ATPS co-flow control is designed based on the previous work by Valencia, L., et al. [40]. Unlike the previous fabrication method, we 3D printed our chip and applied a customized post-processing protocol to achieve maximum optical transparency [41]. The chips were printed using a Phrozen Sonic Mini 8K Resin 3D Printer and Monocure3D PRO Crystal Clear Resin. The device consists of two inlets to establish vertical ATPS co-flow in a main channel (1 mm wide, 2 mm deep, and 40 mm long, FIG. 6a). These dimensions were selected to provide a stable printing base and sufficient depth for stacking multiple printing layers. This configuration allows for multiple printing layers to be easily stacked. Furthermore, the channels are extruded to enable side imaging of the device and characterization of the vertical co-flow and printed layers (FIG. 6B).

### 3. ATPS Reagents and Materials

The printing phase is a PEG-DA solution prepared following an existing protocol [39]. Briefly, we mixed the photoinitiator Phenylbis(2,4,6-trimethylbenzoyl) phosphine oxide (BAPO) (Sigma-Aldrich) in PEG-DA (575 mw, Sigma-Aldrich) at a 4% weight/weight concentration to form the photopolymer solution. The blocking phase is a dextran solution prepared at a 20% weight/volume concentration using double-filtered deionized water. The dextran, sourced from Sigma-Aldrich, is derived from Leuconostoc mesenteroides with an average molecular weight of 150,000 Da. The blocking phase does not polymerize but serves as a programmable spacer to control the thickness of the printing phase. Dextran solution is chosen because without coupling specific crosslinkable functional groups [42, 43], dextran is not commonly known as a photopolymerizable material that could undergo free-radical chain-growth polymerization in light-based 3D printing [44].

### 4. Numerical Simulation

To estimate the phase boundary location in the ATPS co-flow, we used COMSOL MULTIPHYSICS 6.1 to simulate a 3D-rendered numerical model that replicates the experimental design of the microfluidic chip. 699878 domain elements, 42798 boundary elements, and 1926 edge elements were used in the simulations. Fine mesh was used at the structure surface and liquid-liquid interface. The level set method was used to numerically compute a moving interface or boundary using a fixed mesh. The modeling of the interface solves the following equation to be able to move the interface with uu, the velocity field:

$$\frac{\partial ϕ}{\partial t} + u \cdot ∇ ϕ = γ ∇ \cdot ( ε ∇ ϕ - ϕ ( 1 - ϕ ) \frac{∇ ϕ}{\vert ∇ ϕ \vert} )$$

The terms on the right-hand side are necessary for numerical stability while the terms on the left-hand side give the correct motion of the interface. The φ parameter is a smooth step function which equals zero in one phase and 1 in the other. The ε parameter is used to determine the thickness of the region of the interface where φ transitions from 0 to 1. We chose the ε at the half of the maximum mesh element size to precisely represent the interfacial region [45]. The max element size was 1.72×10⁻⁴ so following the expression, 8.6×10⁻⁵ was reported for the ε parameter. The parameter γ determines the amount of stabilization of the level set function. An appropriate value for γ is the maximum magnitude of the velocity field, u. Therefore, the velocity was set to be umax at every reinitialization interval. The material parameters used in the simulation were density of PEG-DA at 1095 kg/m³ and dynamic viscosities of PEG-DA at 20.88 mPa·s; while those for Dextran were 1038 kg/m³ and 22.11 mPa·s, respectively. The material parameters were measured in house.

### 5. Imaging Experiment and Analysis

The microfluidic chip, the co-flow profile, and the in-situ polymerized structure were imaged from the side of the microchannel by fluorescence microscopy using an Echo Revolve microscope or a Leica M205 FCA microscope Thunder MO model. All images were analyzed and quantified using ImageJ.

### B. Results and Discussion

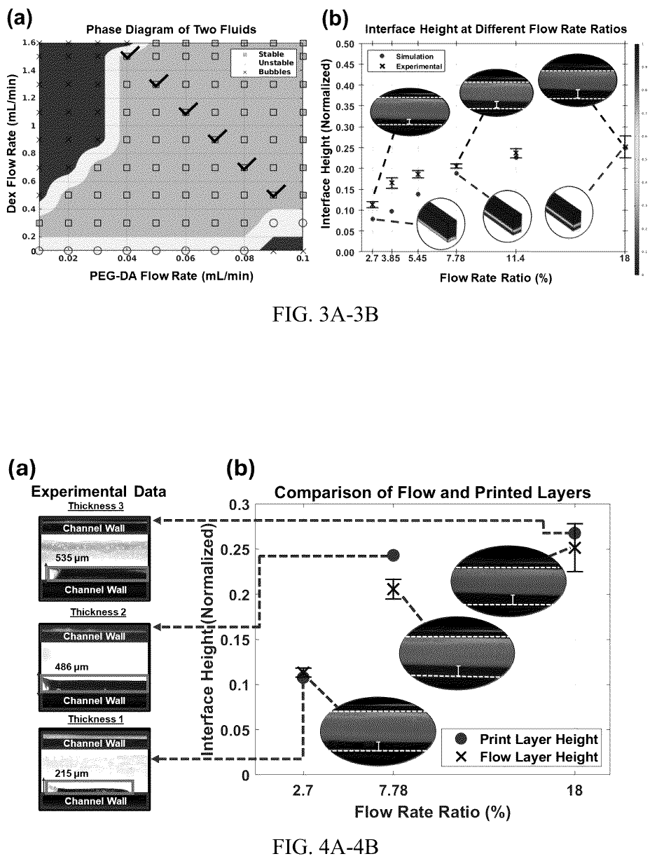

We first sought to identify the condition to establish a stable and planar phase boundary between the printing and blocking phase in our vertically aligned ATPS set up. To monitor the interface, we specifically designed a microfluidic chip with a protruding channel (FIG. 6) and imaged the microchannel from its side. By testing a variety combination of the inlet flow rates of these two phases, we characterized the stability of the co-flow system of PEG-DA and dextran (Dex) in FIG. 3A. The ATPS interface was shown to be stabilized under certain flow rate conditions within 5 seconds by simulation (FIG. 7); hence all characterization and following experiments were performed 10 seconds after the adjustment of flow rates. The area in green (FIG. 3A) represents the flow rate combinations that establish a stable interface between the two phases; while the areas in yellow represent an unstable interface that takes too long to reach a laminar flow profile. The red areas indicate that droplets of one phase are generated, and no planar interface could be observed, making the system inoperable for our purpose. We then chose the flow rate combinations from the green area in all experiments, in particular, the combinations marked with a black checkmark (FIG. 3a). The flow rate combinations were characterized by the percentage ratio between the PEG-DA flow rate and the Dex flow rate in later experiments. A series of small flow rate ratios including the smallest possible value (2.7%) were chosen to test the dynamic control of the thinnest printing layer (PEG-DA phase), which could determine the resolution in the Z-dimension of the IS-3DP method. Six different flow rate combinations were selected to provide a gradual yet observable modulation of the thickness of the printing layer. In particular, the flow rate of the printing phase (PEG-DA) was much smaller than the flow rate of the blocking phase (dextran phase) to allow for a thin printing layer and demonstrate the conservation of the printing material using our method. The location of the co-flow phase boundary, characterized by the normalized interface height in the microchannel, was simulated in COMSOL under different flow rate ratios and later tested experimentally (FIG. 3b, N=4 for each experimental condition). Experimentally, 1 mM sodium fluorescein salt was added in the Dex blocking solution to visualize the layer thickness and location of the interface under fluorescence imaging. The resulting interface height was normalized against the overall channel height of 2 mm with 0 indicating the bottom of the channel and 1 the top of the channel. Our results (FIG. 3b) show that the location of the phase boundary, hence the thickness of the PEG-DA printing layer, can be controlled by specifying the flow rate combination. The experimental and simulation results were largely in agreement (FIG. 3b). The average difference of the normalized interface height between the experimental and simulation values is around 3%. We intentionally chose small flow rates of PEG-DA, about an order of magnitude smaller than the one of Dex. This way we attempted to create the PEG-DA printing layer as thin as possible and ensured that the next polymerization step can be completed rapidly. It is worth noting that when flow rate ratio was less than 7% (small PEG-DA flow rate), the experimental interface height was larger than the simulation result. This is likely because when the PEG-DA flow rate was small, the inaccuracy of the syringe pump and the perturbation in fluid flow due to inconsistent tubing connections could become significant, affecting the co-flow system and limiting the printing resolution in the Z-dimension.

Next, we sought to verify if the photo-polymerization step altered the thickness of the PEG-DA layer before and after the polymerization. Shown in FIG. 4a, three flow rate ratios, 2.7%, 7.78%, and 18% were selected to compare the thickness of the printed structure with the pre-polymerization interface height. These ratios were chosen as they cover the range of selected flow rate conditions from FIG. 3a and provide appreciable difference in layer thickness. Each layer was exposed to a 405 nm UV light for 1-2.5 seconds, depending on the expected layer thickness. The light exposure time was selected to ensure polymerization of only the intended region based on the mask. The printed layer thickness was measured in fluorescence imaging by filling the rest of channel with 1 mM sodium fluorescein solution. We observed that the printed layer, highlighted in green in FIG. 3a, compared with the flowing layer (in FIG. 4b), were consistent with each other within a 3% difference on average. This experiment validates the efficacy of our 2-step printing procedure to yield a printed layer as defined by the ATPS co-flow profile.

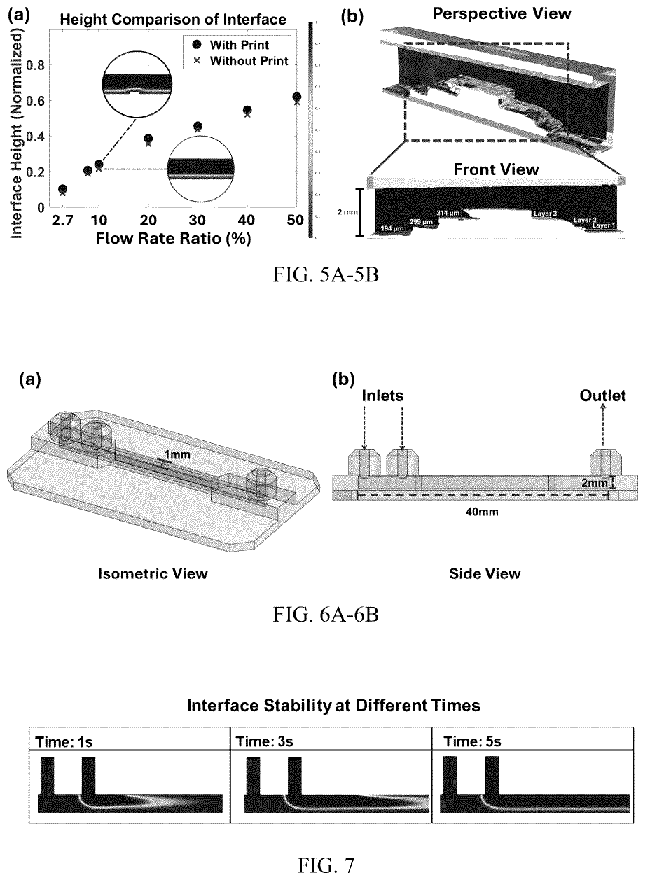

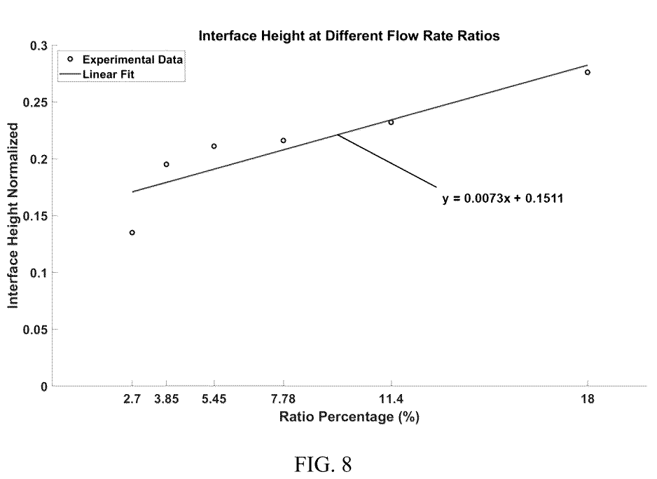

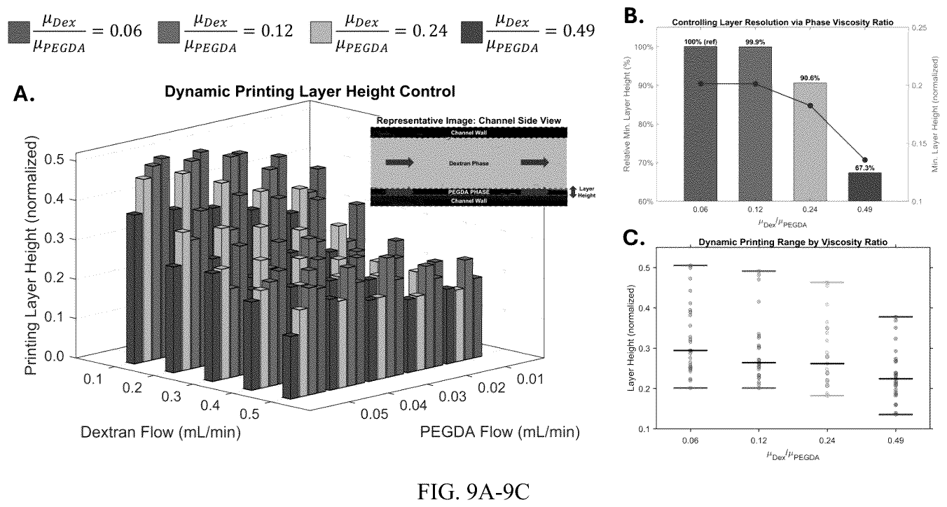

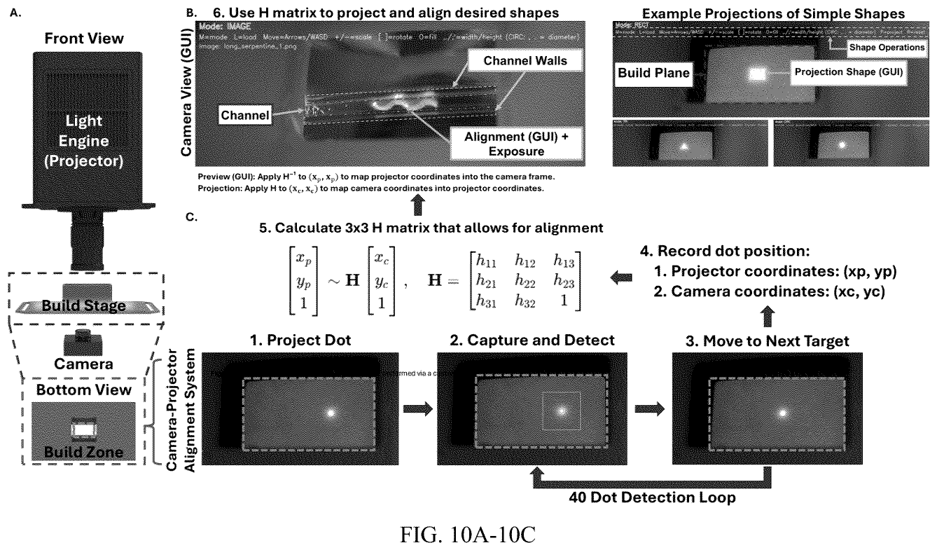

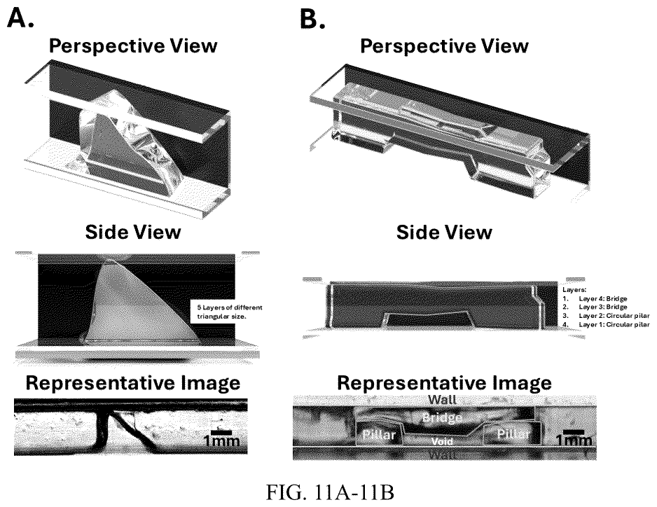

Finally, we sought to create 3D object using the IS-3DP concept. Prior to the experiment, we conducted a simulation analysis to examine how much the layer formation could be altered when a printed layer already exists. Shown in FIG. 5a, we compared the interface height in a straight channel (the distance between the interface and the channel wall) with interface height on an existing printed layer (the distance between the interface and the edge of an internal structure within the channel). The simulation result shows that although the existing structure does affect the interface profile, the interface height on top of the existing structure is comparable to the one in a straight channel and can be tuned by the flow rate ratio in a similar manner. Such tunability of the interface height on existing structure is validated in a larger range of the flow rate ratio (2.7% to 50% in FIG. 5a.) This suggests that 3D stacking of polymerized structures up to half of the channel height is possible under the multi-phase continuous flow and that layer formation can be predicted and programmed by the flow rate ratios.

Subsequently, we performed a proof-of-concept experiment to achieve a 3-layer 3D structure in the microchannel by the sequential IS-3DP printing (FIG. 5b). These three layers used differing mask sizes and employed the three flow rate ratios from the previous experiments (2.7%, 7.78%, and 18%). The resulting structure was imaged in fluorescence microscopy with the rest of channel filled with 1 mM sodium fluorescein solution and in a 10-slice z-stack (100 μm z-step) to create a 3D demonstration. FIG. 4b shows 3D view of the printed object inside the channel with different layer thicknesses and XY structures. Qualitatively, the result validates the capability of the IS-3DP concept to create 3D structures in the microchannel. Quantitatively, we measured the layer thickness of these 3 layers, shown in the Front View in FIG. 5b. The thickness of the first layer (194 μm) is comparable with the previous result from FIG. 4 under the same flow rate ratio (215 μm). However, the thicknesses of subsequent layers (299 μm and 314 μm) exhibit an appreciable difference compared with previous prediction (485 μm and 535 μm in FIG. 4). We believe that because the absolute flow rate of the PEG-DA printing phase is much smaller than the blocking Dex phase, the prior printing structure, both the XY-pattern and the Z-thickness, will affect the flow structure and alter the subsequent layer to a certain degree. The printed layer thickness will be eventually determined by the coupling between light penetration and focusing depth and the multi-phase flow profile. More complicated 3D structures, such as overhangs, could be further achieved by precise layer control via adding photoinhibitors in the printing phase or implementing a multicolor light system to alternatively activate and inhibit the polymerization reaction [44, 46].

### REFERENCES

1. Bhattacharjee, N., et al., Lab on a Chip, 2016, 16, 1720.
2. Shafique, H., et al., Lab on a Chip, 2024, 24, 2774.
3. Kulasinghe, A., et al., Scientific Reports, 2017, 7, 42517.
4. Hinnen, H., et al., Micromachines, 2023, 14, 1286.
5. Gong, H., et al., Lab on a Chip, 2016, 16, 2450.
6. Olanrewaju, A. O., et al., Lab on a Chip, 2016, 16, 3804.
7. Ding, L., et al., Bioresources and Bioprocessing, 2022, 9, 1.
8. Prabhakar, P., et al., Frontiers in Nanotechnology, 2021, 3, 685704.
9. Yafia, M., et al., Nature, 2022, 605, 464.
10. Bertana, V., et al., Journal of Vacuum Science & Technology B, 2017, 36, 012001.
11. Collingwood, J., et al., Materials Today: Proceedings, 2023, in press.
12. Carnero, B., et al., Mater Sci Eng C Mater Biol Appl, 2021, 129, 112388.
13. Boaks, M., et al., Micromachines, 2023, 14, 1589.
14. Ahmed, I., et al., Biosensors, 2022, 12, 652.
15. Jian, B., et al., International Journal of Extreme Manufacturing, 2024, 6, 012001.
16. Bhanvadia, A. A., et al., Communications Materials, 2021, 2, 1.
17. Geng, Q., et al., Nature Communications, 2019, 10, 1.
18. Emons, M., et al., Optical Materials Express, 2012, 2, 942.
19. Kuo, A. P., et al., Advanced Materials Technologies, 2019, 4, 1800395.
20. Naderi, A., et al., Annual Review of Biomedical Engineering, 2019, 21, 325.
21. Huang, J., et al., Processes, 2020, 8, 1138.
22. Lee, M. P., et al., Scientific Reports, 2015, 5, 9875.
23. Gong, H., et al., Lab on a Chip, 2017, 17, 2899.
24. Cheng, J., et al., Nature Communications, 2022, 13, 1.
25. Kim, Y. T., et al., Nature Protocols, 2023, 18, 1243.
26. Fan, J., et al., Microfluidics for Pharmaceutical Applications, 2019, 79.
27. Panda, P., et al., Lab on a Chip, 2008, 8, 1056.
28. Paul, R., et al., Nature Communications, 2023, 14, 1.
29. Baah, D., et al., Microfluidics and Nanofluidics, 2012, 12, 657.
30. Gumuscu, B., et al., Biomacromolecules, 2015, 16, 3802.
31. Liu, Q., et al., Angewandte Chemie International Edition, 2019, 58, 547.
32. Ma, S., et al., Small, 2012, 8, 2356.
33. Decock, J., et al., Lab on a Chip, 2018, 18, 1075.
34. Dendukuri, D., et al., Nature Materials, 2006, 5, 365.
35. Seo, H., et al., ACS Applied Materials & Interfaces, 2020, 12, 55467.
36. Pereira, J. F. B., et al., Liquid-Phase Extraction, 2020.
37. Ahmed, T., et al., Annual Review of Analytical Chemistry, 2021, 14, 231.
38. Miri, A. K., et al., Advanced Materials, 2018, 30, 1800242.
39. Lamont, A. C., et al., Lab on a Chip, 2019, 19, 2340.
40. Valencia, L., et al., Scientific Reports, 2021, 11, 1.
41. Garibaldi, G., et al., MRS Communications, 2024, in press.
42. Brunsen, A., et al., Journal of Materials Chemistry, 2012, 22, 19590.
43. Ritz, U., et al., Journal of Materials Chemistry B, 2016, 4, 6552.
44. Yu, C., et al., Chemical Reviews, 2020, 120, 10695.
45. COMSOL, Microfluidics Module User's Guide, 2018.
46. de Beer, M. P., et al., Science Advances, 2019, 5.

1. A method for additive manufacturing of a three-dimensional object comprising:
(a) establishing a multiphasic laminar flow within a microfluidic channel, wherein the multiphasic laminar flow comprises at least a first phase comprising a photopolymerizable resin and a second phase comprising a blocking solution;
(b) adjusting a flow rate ratio between the first phase and the second phase to control a printing layer thickness;
(c) selectively exposing the printing layer to patterned light to polymerize a portion of the photopolymerizable resin, thereby forming a solidified layer; and
(d) repeating the adjusting and selectively exposing steps to build the three-dimensional object layer by layer.

2. The method of claim 1, wherein the multiphasic laminar flow is an aqueous two-phase system (ATPS).

3. The method of claim 1, wherein the photopolymerizable resin comprises poly(ethylene glycol) diacrylate (PEG-DA).

4. The method of claim 1, wherein the blocking solution comprises dextran.

5. The method of claim 1, wherein the flow rate ratio is adjusted to achieve a printing layer thickness of less than 200 μm.

6. The method of claim 1, further comprising integrating multiple materials by switching the photopolymerizable resin in the first phase during the repeating step.

7. The method of claim 1, wherein the patterned light is provided by a light engine comprising a UV projector or a masked UV light source.

8. The method of claim 1, wherein the microfluidic channel is enclosed and eliminates the need for a vat or mechanical build-plate.

9. The method of claim 1, further comprising simulating the multiphasic laminar flow using computational fluid dynamics to predict the printing layer thickness based on the flow rate ratio.

10. A system for additive manufacturing of a three-dimensional object comprising:
(a) a microfluidic device comprising a channel supporting a multiphasic laminar flow, comprising a photopolymerizable resin first phase and an immiscible blocking solution second phase;
(b) one or more pumps configured to adjust a flow rate ratio between the first phase and the second phase to dynamically control a printing layer thickness formed by the first phase;
(c) a light engine configured to selectively expose the printing layer to patterned light to polymerize a portion of the photopolymerizable resin, thereby forming a solidified layer; and
(d) a controller configured to coordinate the one or more pumps and the light engine to build the three-dimensional object layer by layer.

11. The system of claim 10, wherein the microfluidic device is fabricated using stereolithography and comprises two inlets for the first phase and the second phase, and one outlet.

12. The system of claim 10, wherein the light engine comprises a motorized stage for adjusting a focal plane of the patterned light.

13. The system of claim 10, further comprising a camera system for monitoring the printing layer and aligning the patterned light.

14. The system of claim 10, wherein the multiphasic laminar flow is an aqueous two-phase system (ATPS).

15. The system of claim 10, wherein the photopolymerizable resin comprises poly(ethylene glycol) diacrylate (PEG-DA).

16. The system of claim 10, wherein the blocking solution comprises dextran.

17. The system of claim 10, wherein the controller is programmed to adjust the flow rate ratio based on a numerical simulation of the multiphasic laminar flow.

18. The system of claim 10, configured to integrate at least two different photopolymerizable resins by switching inputs to the one or more pumps.

19. A composition for use in multiphasic microfluidic additive manufacturing, comprising:
(a) a first phase comprising a photopolymerizable resin including poly(ethylene glycol) diacrylate (PEG-DA) and a photoinitiator; and
(b) a second phase comprising a blocking solution including dextran, wherein the first phase and the second phase are immiscible and form a stable interface in a laminar flow within a microfluidic channel.

20. The composition of claim 19, wherein the photoinitiator is phenylbis(2,4,6-trimethylbenzoyl) phosphine oxide (BAPO) at a concentration of about 4% weight/weight.

21. (canceled)

22. (canceled)

23. (canceled)

24. (canceled)
